(19) United States
(12) Patent Application Publication
(10) Pub. No.: US 2008/0142884 A1
(43) Pub. Date: Jun. 19, 2008

(54) SEMICONDUCTOR DEVICE

(76) Inventor: Yong-Soo Cho, Daejeon (KR)

Correspondence Address: SHERR & NOURSE, PLLC, 620 HERNDON PARKWAY, SUITE 200, HERNDON, VA, 20170, US

(21) Appl. No.: 11/945,861

(22) Filed: Nov. 27, 2007

(30) Foreign Application Priority Data
Dec. 19, 2006 (KR) 10-2006-0130003

(51) Int. Cl. H01L 29/78; H01L 21/336

(52) U.S. Cl. 257/344; 438/301; 257/E21.437; 257/E29.266

(57) ABSTRACT

Embodiments relate to a semiconductor device, and to a semiconductor device and a method for manufacture that may improve a performance of a MOSFET device. According to embodiments, a semiconductor device may include a gate pattern formed of a gate dielectric layer formed in an active area of a semiconductor substrate and a first gate electrode pattern formed on the gate dielectric layer, an oxide pattern formed at both sides of the first gate electrode pattern, and a second gate electrode pattern formed on the first gate electrode pattern including the oxide pattern, a lightly doping drain (LDD) area formed in the inside of the substrate of the lower area of the oxide pattern, a spacer formed on both side-walls of the gate pattern, source/drain areas formed on the surface of the substrate of both sides of the gate pattern including the spacer, and a salicide film formed in the gate pattern and the source/drain areas.

The present application claims priority under 35 U.S.C. 119 and 35 U.S.C. 365 to Korean Patent Application No. 10-2006-0130003 (filed on Dec. 19, 2006), which is hereby incorporated by reference in its entirety.

### BACKGROUND

A metal oxide silicon field effect transistor (MOSFET) may include a gate electrode and source/drain electrodes formed on a silicon substrate, and a dielectric layer may be positioned therebetween.

As semiconductor devices are designed to emphasize miniaturization, lightweight, and thinness, the size of a MOSFET may also be reduced.

However, such a scale down in size of transistors may reduce an effective channel length of a gate electrode. This, in turn, may generate a short channel effect that may deteriorate punch-through characteristics between the source and the drain.

A shallow junction that forms the source and drain of the MOSFET in a lightly doped drain (LDD) structure may be provided to suppress the short channel effect.

FIG. 1 is a cross-sectional drawing illustrating a related art MOSFET.

Referring to FIG. 1, although not shown, a field area defining an active area may be formed in semiconductor substrate 100. This may be performed by forming a trench by selectively etching substrate 100, for example, by using a dry etch. The trench may then be filled/buried with an insulating material and may be subjected to a chemical mechanical polishing (CMP) to form the field area.

Gate oxide 101 may be formed over semiconductor substrate 100 on which the filled area may be formed. A poly silicon film may be formed on gate oxide 101. A photoresistor process to pattern the gate electrode may then be performed.

Gate oxide 101 on semiconductor substrate 100 may be partially removed by performing an etching process using the photoresist and semiconductor substrate 100 may thus be exposed. In other words, the dry etch process may be performed to form gate electrode pattern 103 and an ion implantation process may be performed to form LDD (Lightly Doped Drain) junction layers 105a and 105b.

A dielectric layer may be formed using an insulating material to form side-wall spacer 107. Thereafter, the dielectric layer on an upper surface of gate electrode pattern 103 may be removed to form side-wall spacer 107. A high-concentration impurity (n+/p+) may be implanted to form source/drain junction layers 109a and 109b.

The related art MOSFET, as described above, may have source/drain junction layers in the LDD structure between the channels of the surface of the substrate. The conductive gate electrode may be formed on an upper portion of the LDD junction layer, and may include a gate dielectric layer therebetween. Moreover, the spacer made of the insulating material may be formed on the side-wall of the gate electrode.

A silicide layer may be formed on the active area of the semiconductor substrate and the upper surface of the gate electrode pattern. Sputtering may then be performed over the substrate to deposit a cobalt (Co) layer and a titanium (Ti) layer. A thermal processing may then be performed.

A metal material on field area and the spacer may not cause a silicide reaction using the thermal processing. A metal material on the active area and the gate electrode, however, may react with the active area and the gate electrode pattern to form the silicide layer.

Thereafter, a cleaning process may be performed on the substrate subjected to the thermal processing using a mixing solution of H₂SO₄ and H₂O₂. The metal material, which may not cause the silicide reaction, may be removed through the cleaning process.

An interlayer dielectric layer may be formed over the substrate on which the silicide layer may be formed. The interlayer dielectric layer may then be planarized by CMP. The interlayer dielectric layer may then be selectively etched and may thereby form a contact hole that exposes the upper surface of the gate electrode and the active area. The contact hole may next be filled with a barrier metal layer and a conductive material to form a conductive contact plug.

A MOSFET device formed as described above may use a poly silicon as a gate electrode material. However, even though the silicide process may be applied to a MOSFET device of 90 nm or less, since the gate electrode may be implemented in about 65 nm, the resistance of the gate electrode may be increased. This may degrade the performance of the transistor.

One possible solution to this problem is to use a fully silicide gate (FSG) or a metal gate. However, many problems should be solved to replace the gate electrode using the currently used poly silicon. In other words, when implementing the gate electrode using the FSG or the metal gate, a process having a detrimental effect on the gate oxide may be performed. Therefore, the process may be very difficult when using the metal gate, and a separate gate insulating material for preventing the infiltration of the metal component into the substrate may be required.

### SUMMARY

Embodiments relate to a semiconductor device, and more particularly to a semiconductor device and a method of forming thereof that may improve performance of a MOSFET device. Embodiments relate to a semiconductor device and a method of forming thereof that may improve a performance of a transistor while using poly silicon when forming a gate electrode of a MOSFET of 90 nm or less.

Embodiments relate to a semiconductor device and a method for forming thereof that may be capable of implementing a poly silicon gate electrode of a nano scale by reducing the thickness of the poly silicon for forming the gate electrode through a process divided into two steps.

According to embodiments, a method for forming a semiconductor device may include forming a gate dielectric layer formed in an active area of a semiconductor substrate and a first gate electrode pattern with a predetermined width on the gate dielectric layer, forming an oxide doped with impurity at both sides of the first gate electrode pattern, forming a second gate electrode pattern with a predetermined width on the first gate electrode pattern including the oxide, forming a gate pattern by etching the oxide using the second gate electrode pattern as a mask in order that a portion of the oxide is formed in the lower of the second gate electrode pattern, forming a lightly doping drain (LDD) area by thermally diffusing impurity into the inside of the substrate of the lower area of the oxide, forming a spacer on both side-walls of the gate pattern, forming source/drain areas by implanting ion into the surface of the substrate of both sides of the gate pattern including the spacer, and forming a salicide film in the gate pattern and the source/drain areas.

According to embodiments, forming the oxide may include stacking an oxide layer doped with the impurity over the substrate including the first gate electrode pattern and performing a planarization process of a chemical mechanical polishing on the oxide layer until the upper surface of the first gate electrode pattern is exposed

According to embodiments, forming the spacer may include coating an insulating material for the spacer on the gate pattern and etching the insulating material for the spacer using an etch back process until the upper surface of the second gate electrode pattern is exposed.

According to embodiments, a semiconductor device may include a gate pattern including a gate dielectric layer formed in an active area of a semiconductor substrate and a first gate electrode pattern formed on the gate dielectric layer, an oxide pattern formed at both sides of the first gate electrode pattern, and a second gate electrode pattern formed on the first gate electrode pattern including the oxide patter, a lightly doping drain (LDD) area formed in the inside of the substrate of the lower area of the oxide pattern, a spacer formed on both side-walls of the gate pattern, source/drain areas formed on the surface of the substrate of both sides of the gate pattern including the spacer, and a salicide film formed in the gate pattern and the source/drain areas.

According to embodiments, the first gate electrode pattern has a thickness of 50 to 100 nm and the second gate electrode pattern has a thickness of 30 to 70 nm.

According to embodiments, the sum of the thickness of the first gate electrode pattern and the second gate electrode pattern is 80 to 150 nm.

According to embodiments, the width of the second gate electrode pattern has a length exceeding one times up to two times the length of the first gate electrode pattern width.

According to embodiments, the gate pattern comprises a poly silicon gate in a “T” letter form formed by the first gate electrode pattern and the second gate electrode pattern.

### DRAWINGS

FIG. 1 is a cross-sectional drawing illustrating a related art MOSFET device.

FIGS. 2a to 2h are cross-sectional drawings illustrating a semiconductor and a method for forming a semiconductor device according to embodiments.

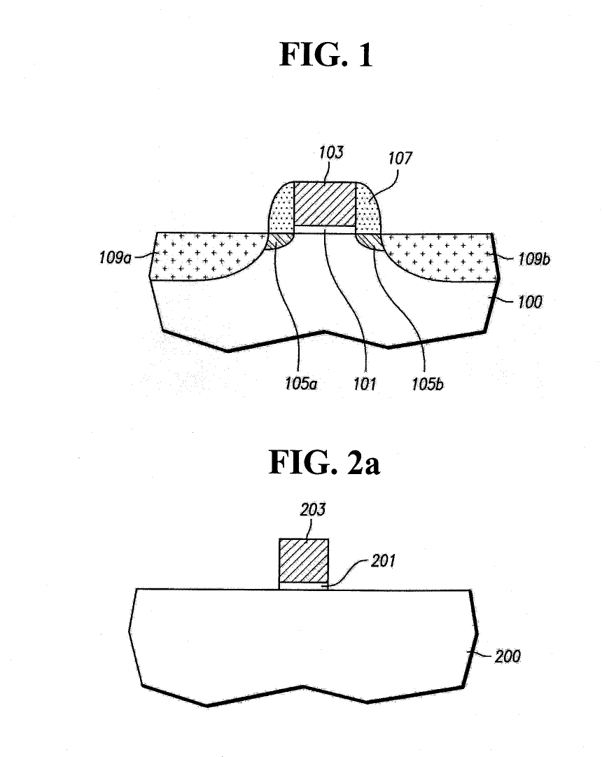

### DESCRIPTION

A dielectric layer may be formed in a field area of a substrate and may define an active area of a semiconductor substrate, for example, a P type or an N type single crystal silicon. A dielectric layer, such as a silicon oxide, may be formed in the field area. In embodiments, the dielectric layer may be formed using a shallow trench isolation (STI) process or a local oxidation of silicon (LOCOS) process, etc.

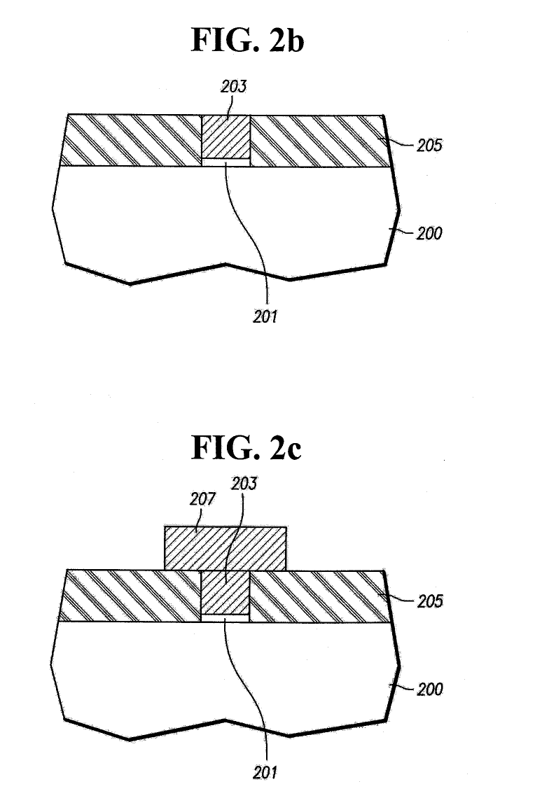

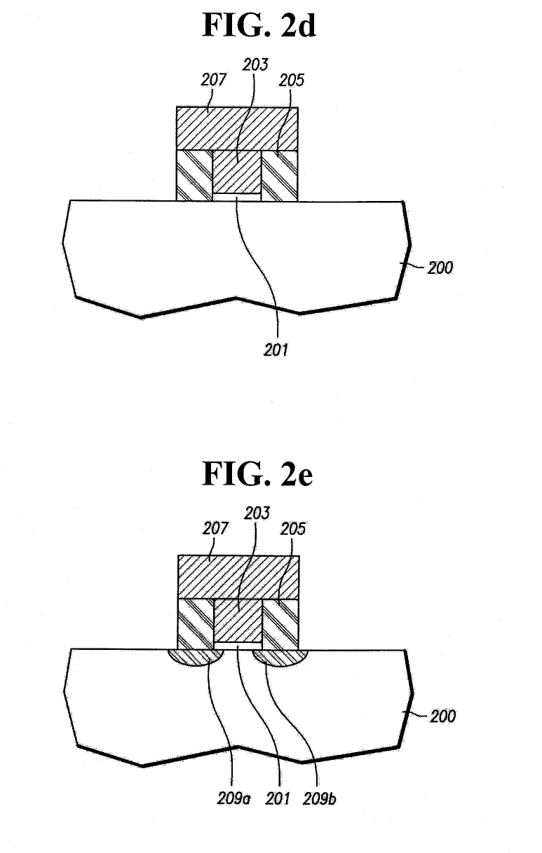

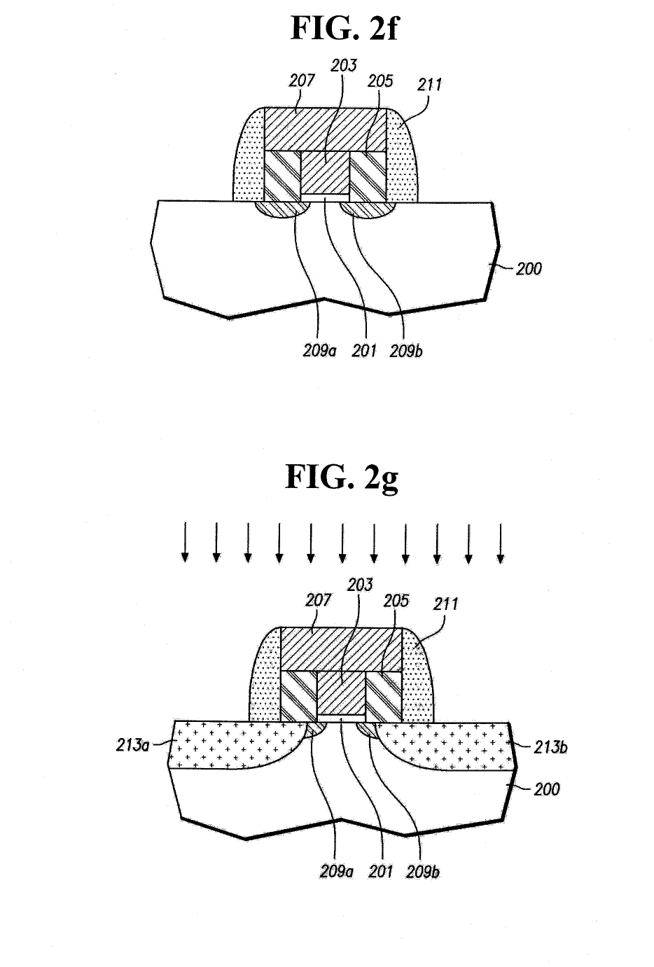

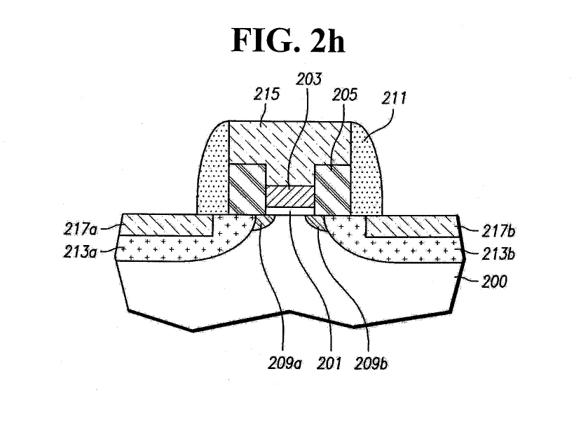

Referring to FIG. 2a, gate dielectric layer 201 may be grown on an active area of substrate 200. In embodiments, the oxide may be grown into gate dielectric layer 201 using a thermal oxidation process.

First gate electrode pattern 203 may be formed on an area of gate dielectric layer 201 on which the gate electrode may be formed. A conductive layer for the gate electrode, for example, a first poly silicon layer may also be stacked at a thickness of approximately 50 to 100 nm on substrate 200 including gate dielectric layer 201. First poly silicon layer may then be etched using a photoresist pattern (not shown) to form first gate electrode pattern 203 on a prescribed area of gate dielectric layer 201. In embodiments, first gate electrode pattern 203 having a height of 50 to 100 nm may thus be formed on substrate 200.

Next, an oxide layer doped with an impurity may be stacked over substrate 200 including first gate electrode pattern 203.

Thereafter, a planarization process of a chemical mechanical polishing may be performed on the stacked oxide layer, for example until the upper surface of first gate electrode pattern 203 is exposed. Therefore, referring to FIG. 2b, oxide 205 may be formed such that it surrounds both sides of first gate electrode pattern 203. According to embodiments, after performing the CMP process on oxide 205, a native oxide may be removed through a wet cleaning process

Referring to FIG. 2c, second gate electrode pattern 207 may be formed to contact the upper surface of exposed first gate electrode pattern 203 and may contact a portion of both sides thereof to oxide 205. According to embodiments, after the wet cleaning process may be performed on oxide 205, a second poly silicon layer with the component as was used when first gate electrode pattern 203 was formed on oxide 205, including first gate electrode pattern 203, may be stacked to a thickness of approximately 30 to 70 nm. The second poly silicon layer may then be etched using the photoresist pattern (not shown) to form second gate electrode pattern 207, which may be wider than the width of first gate electrode pattern 203. At least a portion of a surface of a central side of second gate electrode pattern 207 may contact the overall upper surface of first gate electrode pattern 203. This may make it possible to form the gate electrode in a “T” letter form.

The gate electrode formed on substrate 200 in the “T” letter form using first gate electrode pattern 203 and second gate electrode pattern 207 may be formed at a height within the range not exceeding the thickness of 150 nm. According to embodiments, the thickness may be approximately 80 to 150 nm.

According to embodiments, the width of second gate electrode pattern 207 may be formed exceeding one times, or up to two times, the width of first gate electrode pattern 203.

Consequently, when forming the MOSFET device of 90 nm or less, according to embodiments, when forming the poly silicon gate electrode, two steps may be performed. According to embodiments, after forming the first gate electrode pattern, second gate electrode pattern 207 with the increased width may be formed on first gate electrode pattern 203. Therefore, the poly silicon gate in the “T” letter form may be implemented. The resistance may be reduced using the poly silicon gate in the “T” letter form and the performance of the transistor may thereby be improved.

Next, oxide 205 doped with the impurity may be wet etched using second gate electrode pattern 207 as a hard mask. Referring to FIG. 2d, oxide 205 pattern doped with the impurity may be formed on a lower portion of second gate electrode pattern 207 and at both sides of first gate electrode pattern 203. According to embodiments, the width of oxide 205 pattern may not exceed the area where second gate electrode pattern 207 may be formed.

Through the process, the gate pattern formed of gate dielectric layer 201, the poly silicon gates 203 and 207 in the “T” letter form, and oxide 205 may be formed on substrate 200. Hereinafter, the gate pattern formed of gate dielectric layer 201, the poly silicon gates 203 and 207 in the “T” letter form, and oxide 205 which may be formed on substrate 200 may be referred as to a poly silicon gate pattern, for convenience. According to embodiments, a height of the poly silicon gate pattern may be the sum of the thickness of oxide 205 pattern and the thickness of second gate electrode pattern 207 or the sum of the thickness of gate dielectric layer 201 and the thickness of the two gate electrode patterns 203 and 207.

Referring to FIG. 2e, the impurity may be thermally diffused into the inside of substrate 200 of the lower area of the oxide (205) pattern to form lightly doped drain (LDD) areas 209a and 209b.

According to embodiments, after coating the insulating material for the spacer on the poly silicon gate pattern, the insulating material for the spacer may be etched by an etch back process with anisotropic etching property until an upper surface of second gate electrode pattern 207 may be exposed.

Referring to FIG. 2f, a spacer 211 may thus be formed on both side-walls of the left and right of the poly silicon gate pattern. According to embodiments, spacer 211 may be formed at the left and right of the outer portion of oxide 205 pattern and at both sides of the left and right of second gate electrode pattern 207. According to embodiments, spacer 211 may be formed to have a thickness of approximately 30 to 50 nm using silicon nitride SiN

Referring to FIG. 2g, source/drain areas 213a and 213b may be formed on the surface of substrate 200 at the both sides of the poly silicon gate pattern including spacer 211 using an ion implant process. According to embodiments, the source/drain areas 213a and 213b may be formed to be expanded up to some area of oxide 205 pattern so that they may be formed to be infiltrated up to a portion of lightly doped drain (LDD) areas 209a and 209b.

According to embodiments, to form a subsequent silicide film, a wet cleaning process and a pre-clean process may be performed on the products formed through the foregoing processes using HF solution. The native oxide (not shown), and the like may thus be removed.

According to embodiments, after performing the above described cleaning process, the silicide layer may be formed on the upper surface of the product formed through the foregoing processes and a sputtering may then be performed on the upper thereof to deposit a cobalt (Co) layer or a titanium (Ti) layer. A thermal processing may then be performed.

The material on the field area and spacer 211 may not cause a silicide reaction using the thermal processing. According to embodiments, however, it may react in source/drain areas 213a and 213b of the active area and may react with second gate electrode pattern 207 and first gate electrode pattern 203 of the poly silicon gate pattern.

Referring to FIG. 2h, according to the silicide reaction of embodiments, the first salicide film 215 may be formed in the area reacting with second gate electrode pattern 207 and first gate electrode pattern 203 of the poly silicon gate pattern and a second salicide film 217a and a third salicide film 217b may be formed on an upper portion of source/drain areas 213a and 213b. According to embodiments, the thickness of the respective salicide films may be formed at a thickness exceeding 0 nm up to 70 nm

When the thermal processing is completed, the cleaning process may be performed using a mixing solution of H₂SO₄ and H₂O₂. The metal material, which may not cause the silicide reaction, may be removed through the cleaning process.

According to embodiments, in the MOSFET of 90 nm or less, two steps may be performed when forming the poly silicon gate electrode. For example, after forming the first gate electrode pattern, the second gate electrode pattern with the increased width may be formed on the first gate electrode pattern to form the poly silicon gate electrode in the “T” letter form. According to embodiments, the resistance may be reduced and the performance of the transistor may be improved.

Moreover, the LDD area of embodiments having a decisive effect on the characteristics of the transistor may be formed using the spacer structure using the poly silicon gate. Therefore, since the existing equipment may be used as it is, manufacturing cost may be reduced.

According to embodiments, a poly silicon gate electrode of a nano scale may be implemented by reducing a thickness of the poly silicon for forming the gate electrode through a process divided into two steps. The process margin may thus be secured. According to embodiments, the process divided into two steps may be performed so that when forming the poly silicon gate in the “T” letter form, the thickness of the poly silicon layer may be formed to be approximately 100 nm or less for every the step, which may make it possible to secure the process margin such as a photolithography process, etc. even in the device of the nano scale.

It may be apparent to those skilled in the art that various modifications and variations may be made to embodiments. Thus, it is intended that embodiments cover modifications and variations thereof within the scope of the appended claims. It is also understood that when a layer is referred to as being “on” or “over” another layer or substrate, it may be directly on the other layer or substrate, or intervening layers may also be present.

What is claimed is:

1. A method, comprising:
forming a gate dielectric layer in an active area of a semiconductor substrate, and forming a first gate electrode pattern with a predetermined width over the gate dielectric layer;
forming an oxide doped with impurity at both sides of the first gate electrode pattern;
forming a second gate electrode pattern with a predetermined width over the first gate electrode pattern and the oxide;
forming a gate pattern by etching the oxide using the second gate electrode pattern as a mask such that a portion of the oxide is formed in a lower portion of the second gate electrode pattern;
forming a lightly doping drain (LDD) area by thermally diffusing an impurity into an inside of the substrate of a lower area of the oxide; and
forming a spacer on both side-walls of the gate pattern.

2. The method of claim 1, further comprising:
forming source/drain areas by implanting ions into a surface of the substrate of both sides of the gate pattern including the spacer; and
forming a salicide film in the gate pattern and the source/drain areas.

3. The method of claim 2, wherein the salicide film is formed to have a thickness of 0 nm up to 70 nm.

4. The method of claim 1, wherein forming the oxide comprises stacking an oxide layer doped with the impurity over the substrate including the first gate electrode pattern and performing a planarization process of a chemical mechanical polishing on the oxide layer until an upper surface of the first gate electrode pattern is exposed

5. The method of claim 1, wherein forming the spacer comprises coating an insulating material for the spacer over the gate pattern and etching the insulating material for the spacer using an etch back process until an upper surface of the second gate electrode pattern is exposed.

6. The method of claim 1, wherein the spacer is formed to have a thickness of 30 to 50 nm and comprises silicon nitride SiN

7. The method of claim 1, wherein the first gate electrode pattern is formed to have a thickness of 50 to 100 nm and comprises poly silicon.

8. The method of claim 1, wherein the second gate electrode pattern is formed to have a thickness of 30 to 70 nm and comprises poly silicon.

9. The method of claim 1, wherein a sum of the thickness of the first gate electrode pattern and the second gate electrode pattern is formed to be 80 to 150 nm.

10. The method of claim 1, wherein the predetermined width of the second gate electrode pattern is formed to be greater than the predetermined width of the first gate electrode pattern but no greater than 2 times the predetermined width of the first gate electrode pattern.

11. The method of claim 1, wherein the LDD area is formed in an inside of the substrate of the lower area of the oxide.

12. A device, comprising:
a gate pattern including a gate dielectric layer formed over an active area of a semiconductor substrate, a first gate electrode pattern formed over the gate dielectric layer, an oxide pattern formed at both sides of the first gate electrode pattern, and a second gate electrode pattern formed over the first gate electrode pattern and the oxide pattern;
a lightly doped drain (LDD) area formed in an inside of the substrate of a lower area of the oxide pattern;
a spacer formed on both side-walls of the gate pattern;
source/drain areas formed on a surface of the substrate of both sides of the gate pattern including the spacer; and
a salicide film formed over the gate pattern and the source/drain areas.

13. The device of claim 12, wherein the first gate electrode pattern is configured to have a thickness of 50 to 100 nm.

14. The device of claim 12, wherein the second gate electrode pattern is configured to have a thickness of 30 to 70 nm.

15. The device of claim 12, wherein a sum of thicknesses of the first gate electrode pattern and the second gate electrode pattern is formed to be 80 to 150 nm.

16. The device of claim 12, wherein a width of the second gate electrode pattern is configured exceed a width of the first gate electrode pattern but be no more than 2 times the width of the first gate electrode pattern.

17. The device of claim 12, wherein the gate pattern comprises a poly silicon gate and is configured to have a “T” letter form formed by the second gate electrode pattern over the first gate electrode pattern.

18. A device, comprising:
a substrate;
a first gate electrode having a first height and a first width formed over the substrate;
an oxide layer formed at both sides of the first gate electrode and formed to have the first height;
a second gate electrode formed over the first gate electrode and the oxide layer, and having a second height and a second width, the second width being greater than the first width; and
side wall spacers formed over the substrate at outer edges of the second gate electrode and the oxide layer.

19. The device of claim 18, wherein the first height is configured to be 50-100 nm, and wherein the second height is configured to be 30-70 nm, and wherein a total height of the first and second gate electrodes is less than or equal to 150 nm.

20. The device of claim 19, wherein the second width is no more than 2 times the first width.
